(19) United States
(12) Patent Application Publication
(10) Pub. No.: US 2007/0002535 A1
(43) Pub. Date: Jan. 4, 2007

(54) Flat display apparatus

(76) Inventor: Yeungki Kim, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/477,422

(22) Filed: Jun. 30, 2006

(30) Foreign Application Priority Data
Jul. 4, 2005 (KR) 2005-0059795

(51) Int. Cl. H05K 7/20

(52) U.S. Cl. 361/692; 361/719

(57) ABSTRACT

A flat display apparatus includes a panel for displaying images, a conductive sheet attached to a back surface of the panel, a chassis base for supporting the panel, the chassis base being disposed at a back of the panel while spaced at a predetermined distance from the conductive sheet, and made from synthetic resin and a circuit portion for operating the panel, the circuit portion having a ground portion electrically connected to the conductive sheet. Accordingly, since the conductive sheet is attached to the back surface of the panel and is electrically connected to the ground portion of the circuit portion, the circuit portion can be securely grounded.

### BACKGROUND OF THE INVENTION

1. Field of the Invention

The present invention relates to a flat display apparatus. More particularly, the present invention relates to a flat display apparatus in which a conductive sheet is attached to a back surface of a panel and is electrically connected to a ground portion of a circuit portion in order to secure the ground in a chassis base made from plastic.

2. Description of the Related Art

Recently, various kinds of flat display apparatuses have been developed as substitutes for cathode ray tubes. Such flat display apparatuses include a liquid crystal display apparatus, an electro-luminescence display apparatus, a field emission display apparatus and a plasma display apparatus. Plasma display apparatuses display images using plasma discharge, and, compared with other flat display apparatuses, may easily realize complete digitization and a wide screen.

The plasma display apparatus may include front and back cases, a filter assembly, a plasma display panel (PDP), a heat conductive sheet, a chassis base, a circuit portion, a protective plate, and additional members between the front and back cases. The chassis base may support the PDP disposed in a front portion thereof to display images and may fix the circuit portion for operating the panel to a back portion thereof. The chassis base may function as the support while dissipating heat generated by the PDP and the circuit portion. Therefore, the chassis base may be made from a strong and electrically and thermally conductive material, e.g., aluminum, in order to support the PDP, ground the circuit portion and dissipate heat.

In order to make plasma displays thinner, a thin chassis base is needed. However, if the chassis base is too thin, the support function of the chassis base may be compromised. Therefore, the chassis base should be reinforced with reinforcing material to increase its strength, to prevent the chassis base from being twisted and bent.

On the other hand, as circuit and PDP designs have improved, plasma displays have reduced their energy consumption, resulting in a reduction in the amount of heat and electromagnetic inference generated. There is a continuous effort to substitute an expensive aluminum chassis base with a chassis base made from an inexpensive material, e.g., plastic, e.g., a synthetic resin. A plastic chassis base can be cheaply manufactured, e.g., molded using injection molding. Further, using a plastic chassis base may reduce the number of processing steps, decrease the weight and/or decrease noise of the module.

However, in order for the plastic chassis base to be an acceptable substitute for the aluminum chassis base, the plastic chassis base needs to be able to support the PDP, ground the circuit portion and dissipate heat.

### SUMMARY OF THE INVENTION

The present invention is therefore directed to a flat display, which substantially overcomes one or more of the problems due to the limitations and disadvantages of the related art.

It is therefore a feature of an embodiment of the present invention to provide a flat display which includes a plastic chassis base capable of providing electric connection between a conductive sheet attached to a back surface of a panel and a ground portion of a circuit portion, thereby securing ground for the circuit portion.

It is another feature of an embodiment of the present invention to provide a flat display having reduced weight.

It is yet another feature of an embodiment of the present invention to provide a flat display having reduced noise.

It is still another feature of an embodiment of the present invention to provide a flat display with reduced material and/or manufacturing costs.

At least one of the above and other features and advantages of the present invention may be realized by providing a flat display apparatus including a panel for displaying images, a conductive sheet attached to a back surface of the panel, a chassis base for supporting the panel, the chassis base being disposed at a back of the panel, spaced at a predetermined distance from the conductive sheet, and made of plastic, and a circuit portion for operating the panel, the circuit portion having a ground portion electrically connected to the conductive sheet.

The flat display apparatus may include bosses fixed to the chassis base, each boss having a first end electrically connected to the conductive sheet, and a second end electrically connected to the ground portion of the circuit portion, the first and second ends of each boss being electrically connected. Each boss may be made of conductive material or plastic. If plastic, each boss may include a through hole formed through the plastic and a conductive material filling the through hole to electrically connect the first and second ends. The bosses may be integral with the chassis base.

The flat display apparatus may include conductive members between the conductive sheet and the chassis base, each conductive member may include one side electrically connected to the conductive sheet and another side electrically connected to the first end of each boss. Each conductive member may be made from material capable of absorbing vibration. Each conductive member may be an elastic material coated with a conductive material or a spring. Each conductive member may have the one side in contact with the conductive sheet and the other side in contact with the first end of each boss. At least one side of each conductive member may have a conductive adhesive thereon.

The flat display apparatus may include conductive coupling members coupled to the first end of each boss so as to fix each boss to the chassis base. The conductive coupling members may be between the conductive sheet and the chassis base, each conductive coupling member having one side electrically connected to the conductive sheet and another side electrically connected to each coupling member.

The conductive sheet may be made from material having excellent thermal conductivity and may provide uniform temperature distribution, and may include an aluminum sheet. A thermally conductive sheet may be interposed between the panel and the conductive sheet. The plastic may be a synthetic resin and/or may be transparent.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates an exploded perspective view of a flat display apparatus according to the present invention;

FIG. 2 illustrates a cross-sectional view of a first embodiment of an electric connection between a conductive sheet and a circuit portion;

FIG. 3 illustrates a cross-sectional view of a second embodiment of an electric connection between a conductive sheet and a circuit portion; and

FIG. 4 illustrates a cross-sectional view of a third embodiment of an electric connection between a conductive sheet and a circuit portion.

### DETAILED DESCRIPTION OF THE INVENTION

Korean Patent Application No. 10-2005-0059795, filed on Jul. 4, 2005, in the Korean Intellectual Property Office, and entitled: “Plasma Display Apparatus,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the Figures., the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In accordance with embodiments of the present invention, different materials may be used to provide different functions for a display panel and its associated driving circuit in order to optimize the support structure in the display. For example, a lightweight, strong material, e.g., plastic, may be used for the chassis base, a conductive sheet may be between the chassis base and the panel, bosses may provide electrical communication between a circuit portion supported by the chassis base and the conductive sheet, the conductive sheet may also serve as a heat sink, resilient connectors may be provided between the bosses and the conductive sheet, etc. As used herein, “conductive” is to mean “electrically conductive,” and anything that is to be thermally conductive will be explicitly so-called.

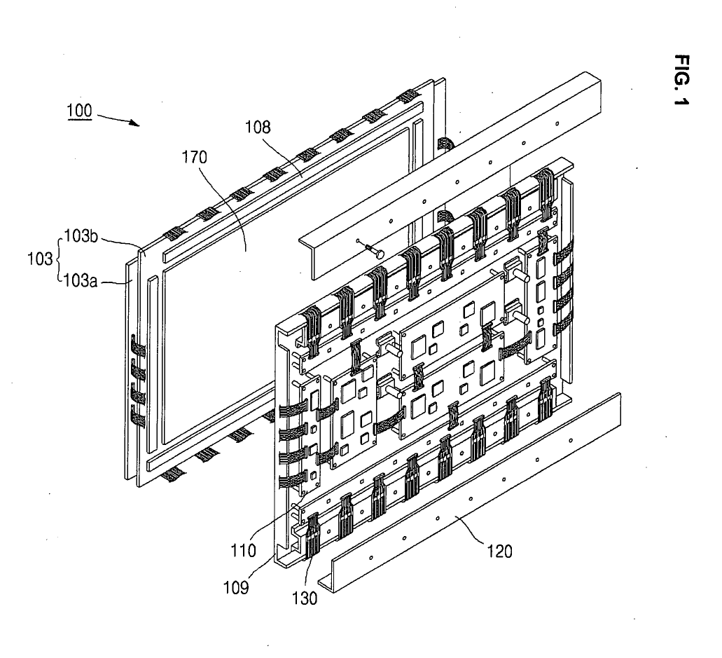

FIG. 1 illustrates a schematic exploded perspective view of a flat display apparatus 100 according to the present invention.

Referring to FIG. 1, the flat display apparatus 100 may include a panel 103, a conductive sheet 170, an adhesive member 108, a chassis base 109, a circuit portion 110, a protective plate 120 and a connecting member 130.

When the panel 103 is a PDP, the panel 103 may display images using discharge generated by driving signals provided from a circuit element formed in the circuit portion 110. In order to display the images, the panel 103 may include two or more substrates 103a and 103b and partitions, electrodes, fluorescent material, dielectric material and a protective film disposed between the substrates. The panel 103 may have spaces, e.g., discharging cells, in which discharges are generated. These cells may be filled with discharge gases which emit ultraviolet light having a wavelength band suitable for exciting the fluorescent material. The panel 103 may be connected to the circuit portion 110 by, e.g., a flexible printed circuit (FPC) or a tape carrier package (TCP), e.g., a film on which some of driving chips are mounted.

According to the present invention, the conductive sheet 170 may serve as a heat sink and may be connected to a ground of the circuit portion 110 to ground the circuit portion 110. The conductive sheet will be described below.

The adhesive member 108 may fix the panel 103 to the chassis base 109. Plural strips of the adhesive member 108 may be provided at a periphery of the conductive sheet 170 to form a frame shape, so as to fix the panel 103 to the chassis base 109. The adhesive member 108 may be, e.g., an adhesive agent, an adhesive sheet or an adhesive tape. The adhesive member 108 may have various thicknesses and shapes, and may be adhered in different manners as suitable for the chassis base 109. When the chassis base is made of a material unsuitable to serve as a heat sink, e.g., a plastic, e.g., a synthetic resin, the adhesive members 108 may be spaced by a predetermined distance from the conductive sheet 170 to allow fluid, e.g., air, to pass through spaces to help the conductive sheet 170 dissipate heat. The adhesive members 108 may be thicker than the conductive sheet 170 so a gap is provided between the conductive sheet 170 and the chassis base 109 to further allow fluid to pass therethrough.

The circuit portion 110 may be fixedly supported to the chassis base 109 by a coupling member, e.g., a screw. When the chassis base 109 is made from an electrically insulating material, e.g., plastic, e.g., synthetic resin, it is difficult to provide a ground to the circuit portion 110.

The circuit portion 110 may include plural circuit boards to operate the panel 103. More particularly, the circuit portion 110 may include an electric power supplying portion, a logic circuit portion, an address circuit portion, a scan circuit portion, a sustain circuit portion and driving buffer boards. The electric power supplying portion may supply electricity to the driving circuit and the panel 103, and may have an AC/DC converter to convert alternating current into direct current. The logic circuit portion may receive image signals, and then may divide and control the signals to be transferred to the address circuit portion, the scan circuit portion and the sustain circuit portion. The logic circuit portion may also control the supply of the electric power. Each circuit portion may receive signals from the logic circuit portion and then transfer signals to its respective driving chip. Each driving chip may distribute the signal in accordance with the output of the logic circuit portion to respective electrodes. The driving buffer boards may be disposed between the panel 103 and the driving boards, and may provide the driving signals from the respective circuit portions to the panel 103. In addition, the driving buffer boards may be connected to the panel 103 by a connecting member 130, e.g., a TCP or a FPC

The protective plate 120 may protect the connecting member 130, as well as the front and back cases, from outer impact, and may prevent damage and malfunction of the connecting member 130 by transferring and dissipating heat from the connecting member 130 to a heat dissipating member (not shown).

When the circuit portion 110 supplies a high voltage to the plural electrodes mounted in the panel 103, the electrodes need to be stably grounded. However, it is difficult to secure the ground for the electrodes when the chassis base 109 is an insulating material, e.g., plastic. The ground for the electrodes will be described below in detail.

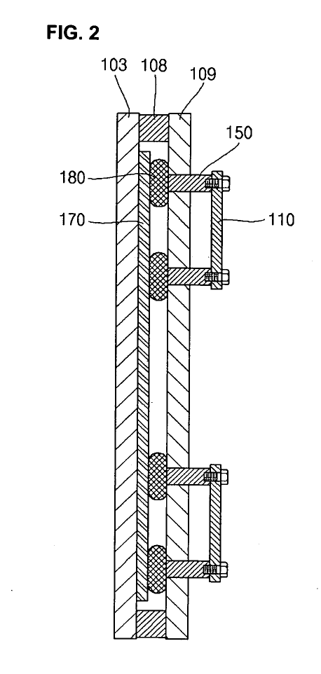

FIG. 2 illustrates a cross-sectional view of a flat display apparatus according to a first embodiment of the present invention.

In the flat display apparatus according to the first embodiment of the present invention, referring to FIG. 2, the panel 103 may have the conductive sheet 170 attached to a back surface thereof and may be fixed by the adhesive members 108 to the chassis base 109. The circuit portion 110 may be supported by the bosses 150 fixedly coupled to the chassis base 109.

An insulating material used for the chassis base 109 may include a synthetic resin, e.g., a polyester resin, an epoxy resin or a polycarbonate resin. The polyester resin may be reinforced with fiberglass and may be referred to as fiber reinforced plastic (FRP). Fiber reinforced plastics (FRPs) may have steel-like-strength and may be made using a recently developed molding method. The polycarbonate resin may be transparent, have excellent mechanical character, be non-toxic, have good heat resistance and be flame retardant. In the description, however, there is no limitation to the above-mentioned synthetic resins.

The conductive sheet 170 may be interposed between the panel 103 and the chassis base 109 to dissipate heat, which may be generated bythe panel 103 during operation thereof, thereby preventing a temperature of the panel 103 from rapidly increasing. Furthermore, the conductive sheet 170 may enable the panel 103 to have a uniform temperature. Therefore, the panel 103 may be prevented from being damaged or malfunctioning due to a local temperature difference.

The conductive sheet 170 may be, e.g., aluminum or carbon. Since aluminum has a higher heat conductivity than carbon, which is generally used as a thermally conductive sheet, use of aluminum enables the panel to have a more uniform temperature distribution. Accordingly, the afterimage effect may be improved.

When the chassis 109 has low heat conductivity and poor heat dissipation, e.g., is made from plastic, the conductive sheet 170 and the chassis base 109 may solve these problems by being spaced apart by a predetermined distance. Further, when aluminum is used for the conductive sheet 170, separation of the conductive sheet 170 and the chassis base 109 may isolate direct transmission of vibration from the circuit portion 110 to the conductive sheet 170, reducing noise.

The conductive sheet 170 may be connected to the ground portion of the circuit portion 110 to function as a ground. The electrical connection between the conductive sheet 170 and the circuit portion 110 will be described.

Each boss 150 may be made of a conductive material and fixed to the chassis base 109. Each boss 150 may have a first end electrically connected to the conductive sheet 170 and a second end electrically connected to the ground portion of the circuit portion 110.

Alternatively, each boss 150 may be made from plastic. When each boss 150 is plastic, each boss 150 may have a through hole filled with conductive material along its length or may have both ends thereof electrically connected with each other. Each boss 150 made from plastic may be integrally formed with the chassis base 109. Thus, separate fixing member is unnecessary, and manufacturing cost and time may be reduced.

When the bosses 150 are not integral with the chassis base 109, i.e., is separately made from the conductive material or plastic, they may be inserted into and fixed to the chassis base 109 during an injection molding of the chassis base 109 of the synthetic material, or fixedly coupled to the chassis base 109 by a coupling member after the injection molding of the chassis base 109.

Referring again to FIG. 2, conductive members 180 may be interposed between the conductive sheet 170 and the chassis base 109. Each conductive member 180 may have one side electrically connected to the conductive sheet 170 and the other side electrically connected to the first end of each boss 150.

The conductive members 180 may respectively electrically connect the conductive sheet 170 to each boss 150. The conductive members 180 may also absorb and offset vibrations of the panel 103 and the circuit portion 110, so as to reduce noise. The conductive members 180 may be an elastic material coated with a conductive material. Each conductive member 180 may have at least one side provided with a conductive adhesive.

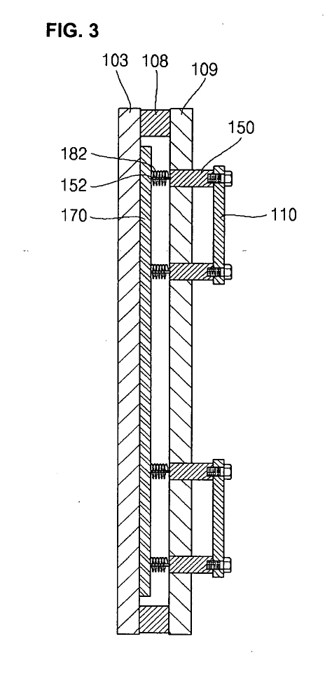

FIG. 3 illustrates a cross-sectional view of a flat display apparatus according to a second embodiment of the present invention.

Referring to FIG. 3, the flat display apparatus, according to the second embodiment of the present invention, may include the panel 103, the conductive sheet 170 attached to the back surface of the panel 103, the chassis base 109 attached by the adhesive member 108 to the panel 103, and the circuit portion 110, which may be supported by bosses 150 fixed to the chassis base 109. The conductive member 182 may be between the conductive sheet 170 and the chassis base 109. The conductive member 182 may have one side electrically connected to the conductive sheet 170 and the other side electrically connected to the first end of each boss 150.

Hereinafter, the description of elements which are the same as those of the above-mentioned first embodiment of the present invention will be omitted.

The conductive member 182 of the flat display apparatus according to the second embodiment of the present invention may include a conductive resilient member, e.g., a metal spring. The use of a conductive resilient member may allow the conductive member 182 to absorb and offset vibrations of the panel 103 and the circuit portion 110, so as to reduce noise, in addition to grounding the circuit portion 110.

The conductive member 182 may have one side contacting the conductive sheet 170 and the other side contacting the first end of each boss 150, so as to bring the conductive sheet 170 into electrical contact with a ground portion of the circuit portion 110. In order to interpose the conductive member 182, e.g., a spring, between the conductive sheet 170 and the first end of each boss 150, a link 152 may be formed at the first end of each boss 150 so that the conductive member 182 may be attached to the link.

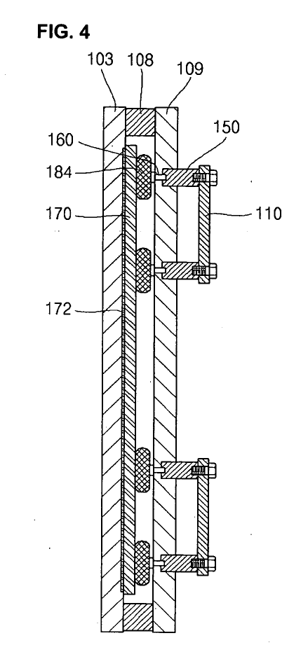

FIG. 4 illustrates a cross-sectional view of a flat display apparatus according to a third embodiment of the present invention.

Referring to FIG. 4, the flat display apparatus, according to the third embodiment of the present invention, may include the panel 103, the conductive sheet 170 attached to the back surface of the panel 103, the chassis base 109 attached by the adhesive member 108 to the panel 103, and the circuit portion 110 supported by bosses 150 fixed to the chassis base 109.

Hereinafter, the description of elements which are the same as those in the above-mentioned embodiment of the present invention will be omitted.

Conductive coupling members 160 may be used to fix the bosses 150 to the chassis base 109. Each conductive coupling member 160 may be coupled at a first end to the first end of each boss 150, so that conductive coupling members 160 can be electrically connected to the bosses 150. If the bosses 150 are conductive, there is no problem in the electrical connection of the bosses 150 to the conductive sheet 170 and the circuit portion 110. However, when the bosses 150 are made from synthetic resin, it is understood that the bosses 150 should have a conductive substance to electrically connect the conductive coupling members 160 to the circuit portion 110, as described above.

Referring again to FIG. 4, conductive members 184 may be interposed between the conductive sheet 170 and the chassis base 109, each of which has one side electrically connected to the conductive sheet 170 and the other side electrically connected to a second end of each conductive coupling member 160. Thus, an electrical connection between a ground portion of the circuit portion 110 and the conductive sheet 170 may be realized. The conductive coupling member 160 may have different widths at its first and second ends. The conductive members 184 can be obtained by coating conductive substance on an elastic material, or may be metal structures such as springs.

The conductive sheet 170 may be made of material having excellent thermal conductivity and capable of distributing a temperature of the panel 103 uniformly, so as to function as a thermally conductive sheet. Alternatively or additionally, a thermally conductive sheet 172 can be further interposed between the panel 103 and the conductive sheet 170.

Although the present invention is illustrated above with general reference to a PDP, it is understood by a person skilled in the art that the present invention can be applied to any flat type of display apparatus to realize the following.

First, by using a plastic chassis base, material and manufacturing costs may be reduced, processing steps may be simplified, and weight and noise of the display may be decreased.

Second, by attaching a conductive sheet to the back surface of the panel and electrically connecting the conductive sheet to the ground portion of the circuit portion, the circuit portion can be securely grounded, improving stability of the display.

Third, by using conductive members that may absorb and/or offset vibration of the circuit portion, noise may be reduced.

Fourth, by using a conductive sheet having excellent thermal conductivity or by providing a thermally conductive sheet between the back surface of the panel and the conductive sheet, the panel may have a uniform temperature distribution and an improved afterimage effect.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A flat display apparatus, comprising:
a panel for displaying images;
a conductive sheet attached to a back surface of the panel;
a chassis base for supporting the panel, the chassis base being disposed at a back of the panel, spaced at a predetermined distance from the conductive sheet, and made of plastic; and
a circuit portion for operating the panel, the circuit portion having a ground portion electrically connected to the conductive sheet.

2. The flat display apparatus as claimed in claim 1, further comprising bosses fixed to the chassis base, each boss having:
a first end electrically connected to the conductive sheet, and
a second end electrically connected to the ground portion of the circuit portion, the first and second ends of each boss being electrically connected.

3. The flat display apparatus as claimed in claim 2, wherein each boss is made of conductive material.

4. The flat display apparatus as claimed in claim 2, wherein each boss is made from plastic

5. The flat display apparatus as claimed in claim 4, wherein each boss comprises:
a through hole formed through the plastic; and
a conductive material filling the through hole to electrically connect the first and second ends.

6. The flat display apparatus as claimed in claim 4, wherein the bosses are integral with the chassis base.

7. The flat display apparatus as claimed in claim 2, further comprising conductive members between the conductive sheet and the chassis base, each conductive member including:
one side electrically connected to the conductive sheet; and
another side electrically connected to the first end of each boss.

8. The flat display apparatus as claimed in claim 7, wherein each conductive member is made from material capable of absorbing vibration.

9. The flat display apparatus as claimed in claim 7, wherein each conductive member is an elastic material coated with a conductive material.

10. The flat display apparatus as claimed in claim 7, wherein each conductive member has the one side in contact with the conductive sheet and the other side in contact with the first end of each boss.

11. The flat display apparatus as claimed in claim 7, further comprising a conductive adhesive on at least one side of each conductive member.

12. The flat display apparatus as claimed in claim 7, wherein each conductive member has a spring structure.

13. The flat display apparatus as claimed in claim 12, wherein each conductive member has the one side in contact with the conductive sheet and the other side in contact with the first end of each boss.

14. The flat display apparatus as claimed in claim 2, further comprising conductive coupling members coupled to the first end of each boss so as to fix each boss to the chassis base.

15. The flat display apparatus as claimed in claim 14, wherein the conductive coupling members are between the conductive sheet and the chassis base, each conductive coupling member having one side electrically connected to the conductive sheet and another side electrically connected to each coupling member.

16. The flat display apparatus as claimed in claim 1, wherein the conductive sheet is made from material having excellent thermal conductivity and provides uniform temperature distribution.

17. The flat display apparatus as claimed in claim 16, wherein the conductive sheet includes an aluminum sheet.

18. The flat display apparatus as claimed in claim 1, further comprising a thermally conductive sheet interposed between the panel and the conductive sheet.

19. The flat display apparatus as claimed in claim 1, wherein the plastic is a synthetic resin.

20. The flat display apparatus as claimed in claim 1, wherein the plastic is transparent.
